(19) United States
(12) Patent Application Publication
(10) Pub. No.: US 2024/0349466 A1
(43) Pub. Date: Oct. 17, 2024

(54) CONVERTER

(71) Applicant: LG INNOTEK CO., LTD., Seoul (KR)

(72) Inventors: Jae Hoo JUNG, Seoul (KR); Ji Hyeon BAIK, Seoul (KR); Yong Bin LEE, Seoul (KR)

(73) Assignee: LG INNOTEK CO., LTD., Seoul (KR)

(21) Appl. No.: 18/701,043

(22) PCT Filed: Nov. 16, 2022
(86) PCT No.: PCT/KR2022/018144

§ 371 Date: Apr. 12, 2024

(30) Foreign Application Priority Data
Nov. 18, 2021 (KR) 10-2021-0159092
Nov. 9, 2022 (KR) 10-2022-0149077

(51) Int. Cl. H05K 7/20; H02M 3/00

(52) U.S. Cl. CPC H05K 7/209; H02M 3/003

(57) ABSTRACT

A converter comprises: a housing; an electronic component disposed in the housing; and heat dissipation fins protruding from the outer surface of the housing, wherein the heat dissipation fins comprise: a plurality of first heat dissipation fins disposed to be spaced apart from each other; and a plurality of second heat dissipation fins disposed to be spaced apart from each other and disposed between the plurality of first heat dissipation fins that are adjacent to each other, and wherein on the basis of a first direction, the lengths of the first heat dissipation fins are longer than the lengths of the second heat dissipation fins.

### TECHNICAL FIELD

The present embodiment relates to a converter.

### BACKGROUND ART

Engine electrical devices (starting devices, ignition devices, and charging devices) and lighting devices are common as automobile electrical devices, but recently, most systems, including chassis electrical devices, are becoming electrically electronic as vehicles become more electronically controlled.

Various electrical components such as lamps, audio systems, heaters, and air conditioners installed in automobiles are designed to receive power from the battery when the car is stopped and from the generator when driving, and at this time, the generation capacity of the 14V power system is used as a normal power supply voltage.

Recently, along with the development of the information technology industry, various new technologies (motor-type power steering, Internet, and the like) aimed to enhance the convenience of automobiles are being adopted by vehicles, and in the future, it is expected that the development of new technologies that can maximally utilize the current automotive systems will continue.

A hybrid electric vehicle (HEV), regardless of soft or hard type, is equipped with a DC-DC converter (Low Voltage DC-DC Converter) for supplying an electric load (12V). In addition, the DC-DC converter, which serves as a generator (alternator) of a general gasoline vehicle, supplies a voltage of 12V for an electric load by lowering the high voltage of a main battery (usually a high-voltage battery of 144V or more).

A DC-DC converter refers to an electronic circuit device that converts DC power of a certain voltage into DC power of another voltage, and is used in various fields such as television receivers and electrical components of automobiles.

Inside a converter, a number of electrical elements that generate heat by driving are disposed. In general, the heat dissipation of the converter can be achieved by arranging one or more heat dissipation fins on an outer surface of the housing that forms the external shape. In other words, it is a structure in which the heat generated from the electrical elements is conducted to the outside through the housing and dissipated to the outside through the heat dissipation fin.

However, considering that the amount of heat generated is different for each electronic component and that the overall weight of the converter increases due to the arrangement region of heat dissipation fins, there is difficulty in designing the heat dissipation structure.

### DETAILED DESCRIPTION OF THE INVENTION

### Technical Subject

The present embodiment is intended to provide a converter that can improve heat dissipation efficiency and reduce weight.

### Technical Solution

A converter according to the present embodiment comprises: a housing; an electronic component being disposed inside the housing; and heat dissipation fins being protruded from an outer surface of the housing, wherein the heat dissipation fins comprise: a plurality of first heat dissipation fins being disposed to be spaced apart from one another; and a plurality of second heat dissipation fins being disposed to be spaced apart from one another and disposed between the plurality of first heat dissipation fins that are adjacent to each other, and wherein based on a first direction, the lengths of the first heat dissipation fins are longer than the lengths of the second heat dissipation fins.

The outer surface of the housing includes: a first region where the first heat dissipation fins are disposed; and a second region where the first heat dissipation fins and the second heat dissipation fins are disposed, wherein the length of the second region is equal to or less than ½ of the sum of the length of the first region and the length of the second region.

A first gap is formed between pluralities of adjacent first heat dissipation fins in the first region, a second gap is formed between the first heat dissipation fins and the second heat dissipation fins in the second region, and the first gap may be larger than the second gap.

A third gap is formed between the two first heat dissipation fins being disposed at the center based on a second direction perpendicular to the first direction, and the third gap may be larger than the first gap.

A bracket being protruded outward and including a coupling hole is disposed on a side surface of the housing, and a rib connecting the bracket and the first heat dissipation fins or the bracket and the second heat dissipation fins may be included.

The rib may have a shape being protruded from a surface of the housing.

The first heat dissipation fins includes: a first guide region whose one end is disposed adjacent to one side surface of the housing; and a first heat dissipation region being connected to the first guide region and having one end being disposed adjacent to the other side surface of the housing, wherein an inclined surface may be disposed on a surface of the first guide region in a shape that the height of the protrusion from an outer surface of the housing increases as it approaches the first guide region.

The second heat dissipation fins includes: a second guide region whose one end is disposed adjacent to one end of the second region; and a second heat dissipation region being connected to the second guide region and having one end being disposed adjacent to the other end of the second region, wherein an inclined surface may be disposed on a surface of the second guide region in a shape that the height of the protrusion from an outer surface of the housing increases as it approaches the second heat dissipation region.

A connection portion having a larger cross-sectional area than other regions may be disposed between the first guide region and the first heat dissipation region.

A converter according to another embodiment comprises: a first housing; a second housing being disposed at a lower portion of the first housing; an electronic component being disposed between the first housing and the second housing; and heat dissipation fins being protruded downward from a lower surface of the second housing, wherein the heat dissipation fins comprise: a plurality of first heat dissipation fins being disposed to be spaced apart from one another; a plurality of second heat dissipation fins being disposed to be spaced apart from one another and disposed between a plurality of adjacent first heat dissipation fins, and wherein a lower surface of the second housing comprises: a first region where the first heat dissipation fins are disposed; and a second region where the first heat dissipation fins and the second heat dissipation fins are disposed.

### Advantageous Effects

The present embodiment has advantages in that heat dissipation efficiency is enhanced in regions where heat generation is concentrated and at the same time the weight of a converter can be reduced by forming a plurality of heat dissipation regions with an arrangement structure of heat dissipation fins of different lengths,

### BRIEF DESCRIPTION OF DRAWINGS

FIG. 1 is a perspective view illustrating an upper surface of a converter according to an embodiment of the present invention.

FIG. 2 is a perspective view illustrating a lower surface of a converter according to an embodiment of the present invention.

FIG. 3 is a view illustrating FIG. 2 from another angle.

FIG. 4 is a plan view illustrating a side surface of a converter according to an embodiment of the present invention.

FIG. 5 is an exploded perspective view of a converter according to an embodiment of the present invention.

FIG. 6 is a plan view illustrating a lower surface of a converter according to an embodiment of the present invention.

FIG. 7 is a plan view illustrating a lower surface of a converter according to a second embodiment of the present invention.

FIG. 8 is a table comparing the heat dissipation efficiency of the converter according to a second embodiment of the present invention with the converter according to a first embodiment of the present invention.

### BEST MODE

Hereinafter, preferred embodiments of the present invention will be described in detail with reference to the accompanying drawings.

However, the technical idea of the present invention is not limited to some embodiments to be described, but may be implemented in various forms, and inside the scope of the technical idea of the present invention, one or more of the constituent elements may be selectively combined or substituted between embodiments.

In addition, the terms (including technical and scientific terms) used in the embodiments of the present invention, unless explicitly defined and described, can be interpreted as a meaning that can be generally understood by a person skilled in the art, and commonly used terms such as terms defined in the dictionary may be interpreted in consideration of the meaning of the context of the related technology.

In addition, terms used in the present specification are for describing embodiments and are not intended to limit the present invention.

In the present specification, the singular form may include the plural form unless specifically stated in the phrase, and when described as “at least one (or more than one) of A and B and C”, it may include one or more of all combinations that can be combined with A, B, and C.

In addition, in describing the components of the embodiment of the present invention, terms such as first, second, A, B, (a), and (b) may be used. These terms are merely intended to distinguish the components from other components, and the terms do not limit the nature, order or sequence of the components.

And, when a component is described as being ‘connected’, ‘coupled’ or ‘interconnected’ to another component, the component is not only directly connected, coupled or interconnected to the other component, but may also include cases of being ‘connected’, ‘coupled’, or ‘interconnected’ due that another component between that other components.

In addition, when described as being formed or arranged in “on (above)” or “below (under)” of each component, “on (above)” or “below (under)” means that it includes not only the case where the two components are directly in contact with, but also the case where one or more other components are formed or arranged between the two components. In addition, when expressed as “on (above)” or “below (under)”, the meaning of not only an upward direction but also a downward direction based on one component may be included.

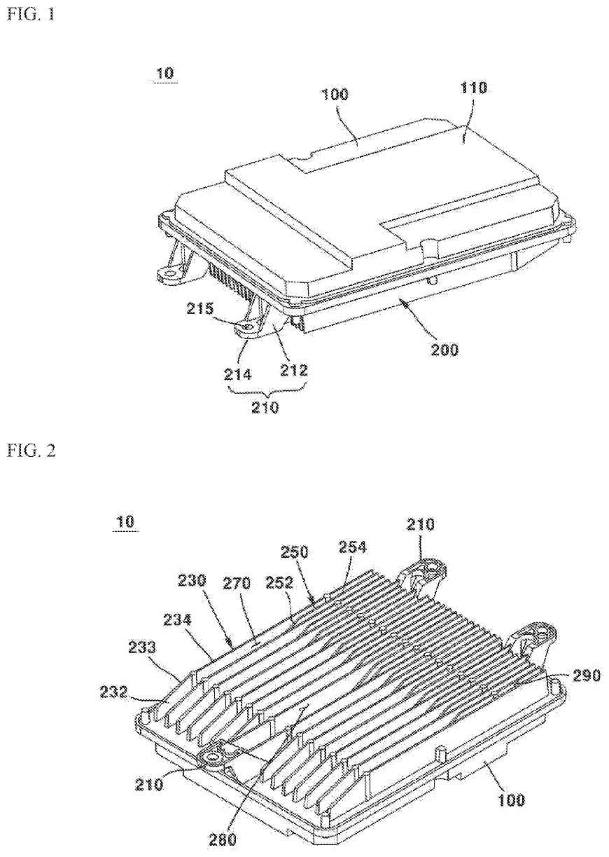

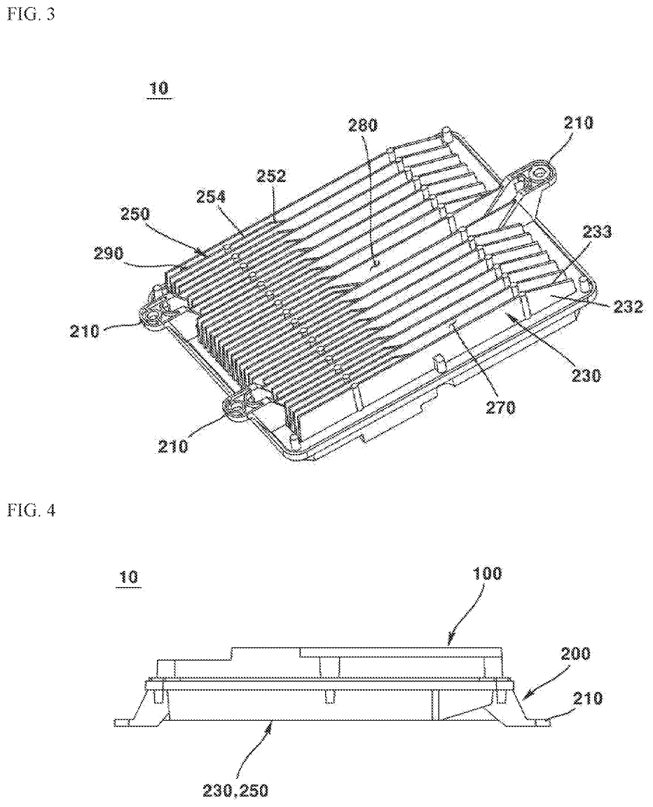

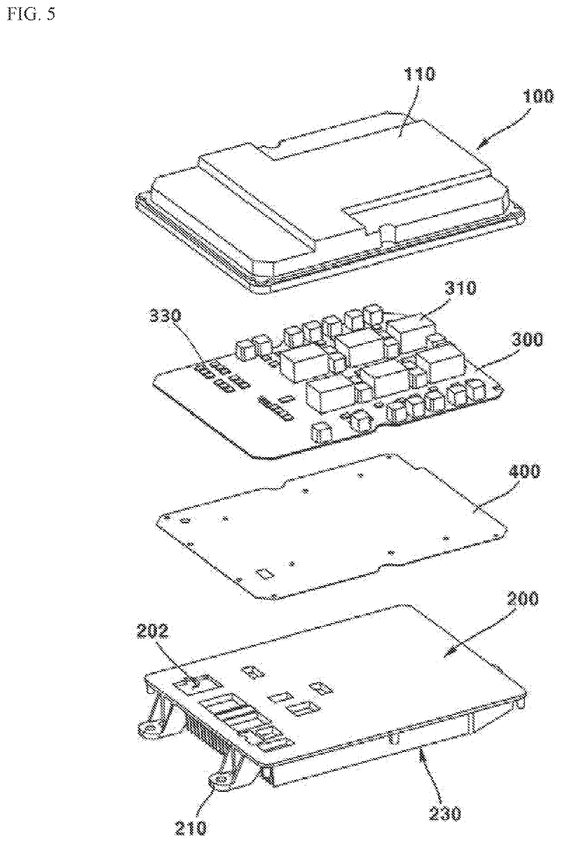

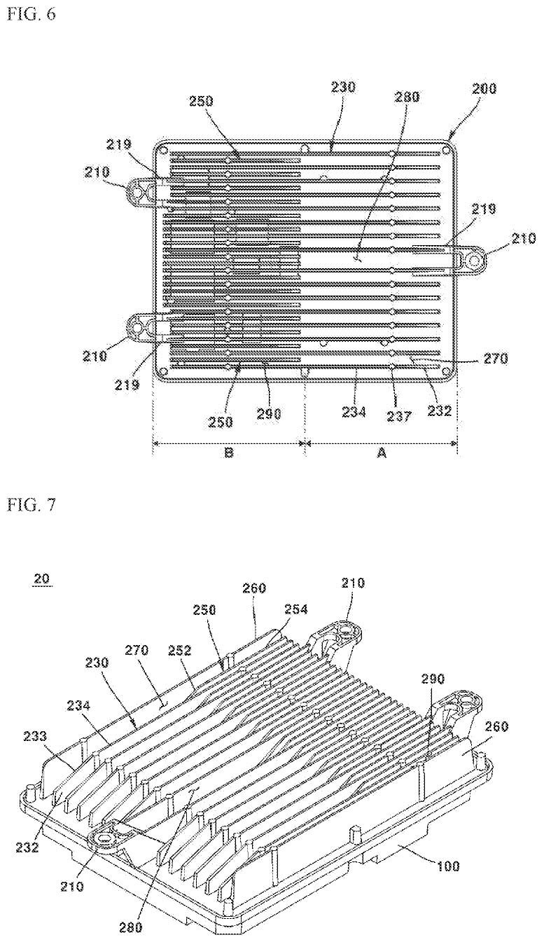

FIG. 1 is a perspective view illustrating an upper surface of a converter according to an embodiment of the present invention; FIG. 2 is a perspective view illustrating a lower surface of a converter according to an embodiment of the present invention; FIG. 3 is a view illustrating FIG. 2 from another angle; FIG. 4 is a plan view illustrating a side surface of a converter according to an embodiment of the present invention; FIG. 5 is an exploded perspective view of a converter according to an embodiment of the present invention; and FIG. 6 is a plan view illustrating a lower surface of a converter according to an embodiment of the present invention.

Referring to FIGS. 1 to 6, an external shape of a converter 10 according to an embodiment of the present invention may be formed by the coupling of the first housing 100 and the second housing 200. The first housing 100 and the second housing 200 may be coupled in an up and down direction. The first housing 100 and the second housing 200 may include screw holes being formed in corresponding regions, and may be screw-coupled together.

The first housing 100 may be disposed at an upper portion of the second housing 200. A protruded region 110 being protruded more upward than other regions may be disposed at an upper surface of the first housing 100. A groove being recessed more upward than other regions may be formed on a lower surface of the first housing 100 facing the protruded region 110. At least a portion of the electronic component 310 in the printed circuit board 300, which will be described later, may be disposed inside the groove. The first housing 100 may be referred to as a cover in that it covers the upper portion of the component inside the converter 10.

The second housing 200 may be disposed at a lower portion of the first housing 100. The second housing 200 may include an upper surface facing the first housing 100 and a lower surface facing the upper surface. The second housing 200 may be referred to as a base in that it supports the components inside the converter 10 at a lower portion.

The first housing 100 and the second housing 200 may be formed of a metal material.

The second housing 200 may include a bracket 210 for coupling the converter 10 to the arrangement region of the converter 10. The bracket 210 may have an end portion being protruded more outward than the side surface of the first housing 100 or the second housing 200. The bracket 210 may include: a leg portion 212 protruding downward from the lower surface of the second housing 200; and a coupling portion 214 protruding outward from the lower end of the leg portion 212. The leg portion 212 may be disposed inclinedly so that the distance from the side surface of the first housing 100 or the side surface of the second housing 200 increases as it travels downward. The coupling portion 214 is disposed parallel to the first housing 100 or the second housing 200 and may include a coupling hole 215 penetrating from an upper surface to a lower surface. Accordingly, the screw passing through the coupling hole 215 is screw-coupled to the installation surface of the converter 10, so that the converter 10 can be fixed to the installation surface.

The bracket 210 may be provided in plural and disposed to be spaced apart from one another. For example, three brackets 210 are provided, one is disposed on one side surface of the second housing 200, and two may be disposed on the other side surface of the second housing 200 facing the one side surface. In this case, the bracket 210 being disposed on one side and the bracket 210 being disposed on the other side surface may be disposed so as not to be overlapped with each other.

A groove 202 being more recessed than other regions may be formed on an upper surface of the second housing 200. A heat dissipating material with high thermal conductivity may be applied to the groove 202. Or, at least a portion of electronic component being disposed on a surface of the printed circuit board 300, which will be described later, may be disposed in the groove 202.

Meanwhile, in this embodiment, the first housing 100 is disposed at an upper portion and the second housing 200 is disposed at a lower portion as an example, but this is not limited, and the second housing 200 is disposed at an upper portion, and the first housing 100 may be disposed at a lower portion. In addition, the first housing 100 and the second housing 200 may be formed as one body rather than a configuration separable from each other.

Electronic components for driving the converter 10 may be disposed in an internal space of the converter 10 being formed by the coupling of the first housing 100 and the second housing 200. As an example, a printed circuit board 300 may be disposed in the internal space. The printed circuit board 300 is formed in a plate shape, and electronic components 310 and 330 may be disposed on at least one of the upper surface and lower surface. The electronic components 310 and 330 may generate heat as they are driven. The electronic components 310 and 330 may include: a transformer for voltage regulation; an inductor 310 for inductance; and one or more FET elements 330.

A heat dissipation pad 400 may be disposed at a lower portion of the printed circuit board 300 among the internal space. The heat dissipation pad 400 is made of a material with high thermal conductivity and may have a plate shape. The upper surface of the heat dissipation pad 400 may be in contact with the lower surface of the printed circuit board 300, and the lower surface of the heat dissipation pad 400 may be in contact with an upper surface of the second housing 200. Accordingly, heat generated from the electronic components 310 and 330 inside the printed circuit board 300 may be transferred to the second housing 200 through the heat dissipation pad 400.

Hereinafter, the heat dissipation structure of the converter 10 will be described.

The converter 10 may include heat dissipation fins. The heat dissipation fins may be formed to be protruded downward from a lower surface of the second housing 200. The heat dissipation fins can enhance heat dissipation efficiency by increasing the cross-sectional area of the outer surface of the converter 10. The heat dissipation fins may be disposed to be overlapped with the electronic components 310 and 330 in an up and down direction.

The lengthwise direction of the heat dissipation fins can be defined as a direction directing from one side surface of the second housing 200 where one of the plurality of brackets 210 is disposed toward the other side surface of the second housing 200, where two of the plurality of brackets 210 are disposed. Hereinafter, the lengthwise direction of the heat dissipation fins, that is, the direction connecting one side surface and the other side surface of the second housing 200, will be defined and described as a first direction.

The heat dissipation fins may include a plurality of first heat dissipation fins 230 and a plurality of second heat dissipation fins 250. At least some of the plurality of first heat dissipation fins 230 may be disposed between adjacent second heat dissipation fins 250. The plurality of second heat dissipation fins 250 may be disposed between adjacent first heat dissipation fins 230. The length of the first heat dissipation fins 230 in a first direction may be longer than the length of the second heat dissipation fins 250 in a first direction. The length of the second heat dissipation fins 250 in a first direction may be less than or equal to ½ of the length of the first heat dissipation fins 230 in the first direction. The length of the second heat dissipation fins 250 in a first direction may be less than ½ of the length of the second housing 200 in a first direction.

As illustrated in FIG. 6, the lower surface of the second housing 200 can be divided into: a first region A adjacent to one side surface of the second housing 200 and in which only the first heat dissipation fins 230 are disposed; and a second region B adjacent to the other side surface of the second housing 200 and in which the first heat dissipation fins 230 and the second heat dissipation fins 250 are disposed together. The length of the second region B in a first direction may be equal to or less than ½ of the sum of the lengths of the first region A and the second region B in a first direction. The second region B may be disposed to be overlapped with the FET element 330 in an up and down direction.

The first heat dissipation fins 230 may be provided in plural and disposed to be spaced apart from each other. A first gap 270 may be formed between adjacent first heat dissipation fins 230 in the first region A. A second gap 290 may be formed between the first heat dissipation fins 230 and the second heat dissipation fins 250 in the second region B. At least one of the gaps between the pluralities of first heat dissipation fins 230 may have a different length from other gaps. For example, as illustrated in FIGS. 2 and 6, a third gap 280 is formed between two first heat dissipation fins 230 located at the center based on a second direction perpendicular to the first direction may be formed larger than the first gap 270 or the second gap 290. Each of the two first heat dissipation fins 230 being disposed at the center based on the second direction may be connected to the leg portion 212 of the bracket 210.

The first heat dissipation fins 230 may include a first guide region 232 and a first heat dissipation region 234. One end of the first guide region 232 may be disposed adjacent to one side surface of the second housing 200. An end of the first heat dissipation region 234 may be disposed adjacent to the other side surface of the second housing 200. A first inclined surface 233 may be formed on a lower surface of the first guide region 232 in a shape in which the height of the protrusion from a lower surface of the second housing 200 increases as it approaches the first heat dissipation region 234. Accordingly, air flowing in from one side surface of the second housing 200 can be easily guided to the region where the heat dissipation fins are disposed.

A connection portion 237 (see FIG. 6) having a larger cross-sectional area than other regions may be formed between the first guide region 232 and the first heat dissipation region 234. Accordingly, the strength may increase in the connection region between the first guide region 232 and the first heat dissipation region 234. The connection portions 237 may be provided in plural numbers and may be disposed in one region between one end and the other end of the first heat dissipation region 234.

The first heat dissipation fins 230 may be connected to the bracket 210. The first heat dissipation fins 230 may be connected to the leg portion 212 of the bracket 210. The second housing 200 may include ribs 219 being protruded downward from a lower surface and connect the leg portion 212 and the first heat dissipation fins 230. The thickness of the ribs 219 may be greater than the thickness of the first heat dissipation fins 230. By connecting the first heat dissipation fins 230 and the bracket 210, the strength of the first heat dissipation fins 230 can be reinforced.

The second heat dissipation fins 250 may be provided in plural numbers and disposed to be spaced apart from one another. The second heat dissipation fins 250 may be disposed in the second region B. The second heat dissipation fins 250 may be disposed between adjacent first heat dissipation fins 230. A second gap 290 may be formed between the second heat dissipation fins 250 and the adjacent first heat dissipation fins 230. The second gap 290 may be smaller than the first gap 270 or the third gap 280.

The second heat dissipation fins 250 may include a second guide region 252 and a second heat dissipation region 254. The second guide region 252 has one end adjacent to one end of the second region B, and the second heat dissipation region 254 may have an end adjacent to the other end of the second region B. A second inclined surface may be formed on a lower surface of the second guide region 252 in a shape in which the height of the protrusion from the lower surface of the second housing 200 increases as it approaches the second heat dissipation region 254. Accordingly, the air passing through the first region A can be easily guided to the second region B.

The second heat dissipation fins 250 may be connected to the bracket 210. The second heat dissipation fins 250 may be connected to the leg portion 212 of the bracket 210. The second housing 200 may include ribs 219 being protruded downward from the lower surface and connect the leg portion 212 and the second heat dissipation fins 250. The thickness of the ribs 219 may be greater than the thickness of the second heat dissipation fins 250. By connecting the second heat dissipation fins 250 and the bracket 210, the strength of the second heat dissipation fins 250 can be reinforced.

Based on a second direction, two second heat dissipation fins 250 may be disposed between the two first heat dissipation fins 230 being disposed in the center. In this case, the first heat dissipation fins 230 may not be disposed between the two second heat dissipation fins 250. In other words, two second heat dissipation fins 250 may be disposed in the third gap 280. Accordingly, the center of gravity of the converter 10 can be formed uniformly with respect to the center.

As illustrated in FIG. 4, a lower surface of the bracket 210 and a lower surface of the heat dissipation fins may be disposed to be stepped from each other. The lower surface of the bracket 210 may be disposed lower than the lower surface of the heat dissipation fins.

According to the above structure, a plurality of heat dissipation regions are formed by arranging heat dissipation fins of different lengths, which has the advantage of improving heat dissipation efficiency in the region where heat generation is concentrated and at the same time reducing the weight of the converter.

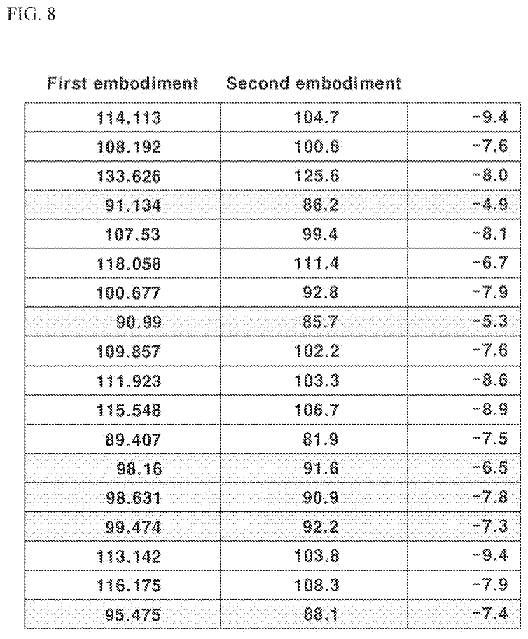

FIG. 7 is a plan view illustrating a lower surface of a converter according to a second embodiment of the present invention; and FIG. 8 is a table comparing the heat dissipation efficiency of a converter according to a second embodiment of the present invention with a converter according to a first embodiment of the present invention.

The present embodiment is the same as the first embodiment in other respects, except that a guide fin is added to the edge of the region where heat dissipation fins are formed. Therefore, hereinafter, only the characteristic parts of the present embodiment will be described, and the description of the first embodiment will be cited as a reference for the remaining parts.

Referring to FIGS. 7 and 8, guide fins 260 may be disposed on an outer surface of the second housing 200 according to the present embodiment. The guide fins 260 may be disposed outside first heat dissipation fins 230 and second heat dissipation fins 250. When a region where the first heat dissipation fins 230 and the second heat dissipation fins 250 are formed on an outer surface of the second housing 200 is referred to as a heat dissipation region, the guide fins 260 may form a boundary of the heat dissipation region. The guide fins 260 may be provided in plural numbers and may be respectively disposed on both sides of the heat dissipation region. The guide fins 260 may be provided in plural numbers and disposed to be spaced apart from one another along a first direction. The first heat dissipation fins 230 and the second heat dissipation fins 250 may be disposed inside the plurality of guide fins 260. The plurality of guide fins 260 may be disposed adjacent to both sides of the lower surface of the second housing 200, respectively.

The protrusion heights of the guide fins 260 from the outer surface of the second housing 200 is the protrusion heights of the first heat dissipation fins 230 from the outer surface of the second housing 200 or the outer surface of the second housing 200, and may be formed to be larger than the protrusion heights of the second heat dissipation fins 250.

The guide fins 260 are formed in a plate shape and may be disposed perpendicular to the lower surface of the second housing 200.

Based on a second direction perpendicular to the first direction, the lengths of the guide fins 260 may correspond to the lengths of the first heat dissipation fins 230 or may be formed to be longer. Based on a lengthwise direction of the guide fins 260, one ends of the guide fins 260 are disposed to form the same heights as one ends of the first heat dissipation fins 230, and the other ends of the guide fins 260 may be disposed to form the same heights as the other ends of the first heat dissipation fins 230 or the other ends of the second heat dissipation fins 250.

According to the above structure, the flow of air flowing through the heat dissipation region is guided through the guide fins 260, so there is an advantage in that heat dissipation efficiency can be further improved. As illustrated in FIG. 8, it can be confirmed that the heat dissipation effect is superior to that of the converter according to the first embodiment due to the air guide structure through the guide fins 260.

In addition, since the heat dissipation region and other regions are partitioned by the guide fins 260, there is an advantage that the space within the heat dissipation region can be protected from other regions, and the degree of freedom in design regarding the arrangement of the plurality of heat dissipation fins within the heat dissipation area can be increased.

Meanwhile, since the guide fins 260 are disposed at the outermost part of the heat dissipation region, they may also be referred to as outermost fins.

In the above description, it is described that all the components constituting the embodiments of the present invention are combined or operated in one, but the present invention is not necessarily limited to these embodiments. In other words, within the scope of the present invention, all of the components may be selectively operated in combination with one or more. In addition, the terms “comprise”, “include” or “having” described above mean that the corresponding component may be inherent unless specifically stated otherwise, and thus it should be construed that it does not exclude other components, but further include other components instead. All terms, including technical and scientific terms, have the same meaning as commonly understood by one of ordinary skill in the art unless otherwise defined. Terms used generally, such as terms defined in a dictionary, should be interpreted to coincide with the contextual meaning of the related art, and shall not be interpreted in an ideal or excessively formal sense unless explicitly defined in the present invention.

The above description is merely illustrative of the technical idea of the present invention, and those skilled in the art to which the present invention pertains may make various modifications and changes without departing from the essential characteristics of the present invention. Therefore, the embodiments disclosed in the present invention are not intended to limit the technical idea of the present invention but to describe the present invention, and the scope of the technical idea of the present invention is not limited by these embodiments. The protection scope of the present invention should be interpreted by the following claims, and all technical ideas within the equivalent scope should be interpreted as being included in the scope of the present invention.

1-10. (canceled)

11. A converter comprising:
a housing;
an electronic component disposed inside the housing; and
heat dissipation fins protruded from an outer surface of the housing,
wherein the heat dissipation fins comprise a plurality of first heat dissipation fins disposed to be spaced apart from one another, and a plurality of second heat dissipation fins disposed to be spaced apart from one another and disposed between the plurality of first heat dissipation fins that are adjacent to each other,
wherein based on a first direction, a lengths of the first heat dissipation fins are longer than a lengths of the second heat dissipation fins, and
wherein the outer surface of the housing includes a first region where the first heat dissipation fins are disposed, and a second region where the first heat dissipation fins and the second heat dissipation fins are disposed.

12. The converter according to claim 11, wherein a length of the second region is equal to or less than ½ of a sum of a length of the first region and the length of the second region.

13. The converter according to claim 11, wherein a first gap is formed between pluralities of adjacent first heat dissipation fins in the first region,
wherein a second gap is formed between the first heat dissipation fins and the second heat dissipation fins in the second region, and
wherein the first gap is larger than the second gap.

14. The converter according to claim 13, wherein a third gap is formed between the two first heat dissipation fins disposed at the center based on a second direction perpendicular to the first direction, and
wherein the third gap is larger than the first gap.

15. The converter according to claim 11, wherein a bracket protruded outward and including a coupling hole is disposed on a side surface of the housing, and
wherein a rib connecting the bracket and the first heat dissipation fins or the bracket and the second heat dissipation fins is included.

16. The converter according to claim 15, wherein the rib has a shape protruded from a surface of the housing.

17. The converter according to claim 11, wherein the first heat dissipation fins includes a first guide region whose one end is disposed adjacent to one side surface of the housing, and a first heat dissipation region connected to the first guide region and having one end disposed adjacent to the other side surface of the housing, and
wherein an inclined surface is disposed on a surface of the first guide region in a shape that the height of the protrusion from an outer surface of the housing increases as it approaches the first guide region.

18. The converter according to claim 12, wherein the second heat dissipation fins includes a second guide region whose one end is disposed adjacent to one end of the second region, and a second heat dissipation region connected to the second guide region and having one end disposed adjacent to the other end of the second region, and
wherein an inclined surface is disposed on a surface of the second guide region in a shape that the height of the protrusion from an outer surface of the housing increases as it approaches the second heat dissipation region.

19. The converter according to claim 17, wherein a connection portion having a larger cross-sectional area than other regions is disposed between the first guide region and the first heat dissipation region.

20. The converter according to claim 14, wherein two second heat dissipation fins are disposed in the third gap.

21. The converter according to claim 11, wherein the electronic component overlaps the second region in a vertical direction.

22. The converter according to claim 11, wherein the electronic components include an inductor and a FET element,
wherein the inductor overlaps the first region, and
wherein the FET element overlaps the second region.

23. The converter according to claim 11, wherein a printed circuit board is disposed in the housing, and the electronic component is coupled thereto, and
wherein a heat dissipation pad is disposed between an inner surface of the housing and the printed circuit board.

24. The converter according to claim 23, wherein the heat dissipation pad is in contact with the printed circuit board.

25. The converter according to claim 11, wherein a groove coated with a heat dissipating material is disposed on an inner surface of the housing facing the second area.

26. A converter comprising:
a first housing;
a second housing disposed at a lower portion of the first housing;
an electronic component disposed between the first housing and the second housing; and
heat dissipation fins protruded downward from a lower surface of the second housing,
wherein the heat dissipation fins comprise a plurality of first heat dissipation fins disposed to be spaced apart from one another, a plurality of second heat dissipation fins disposed to be spaced apart from one another and disposed between a plurality of adjacent first heat dissipation fins, and
wherein a lower surface of the second housing comprises a first region where the first heat dissipation fins are disposed, and a second region where the first heat dissipation fins and the second heat dissipation fins are disposed.

27. The converter according to claim 26, wherein a length of the second region is equal to or less than ½ of a sum of a length of the first region and the length of the second region.

28. The converter according to claim 26, wherein a first gap is formed between pluralities of adjacent first heat dissipation fins in the first region,
wherein a second gap is formed between the first heat dissipation fins and the second heat dissipation fins in the second region, and
wherein the first gap is larger than the second gap.

29. The converter according to claim 26, wherein a third gap is formed between the two first heat dissipation fins disposed at the center based on a second direction perpendicular to the first direction, and
wherein the third gap is larger than the first gap.

30. The converter according to claim 26, wherein a bracket protruded outward and including a coupling hole is disposed on a side surface of the second housing, and
wherein a rib connecting the bracket and the first heat dissipation fins or the bracket and the second heat dissipation fins is included.
